(19) United States
(12) Patent Application Publication
(10) Pub. No.: US 2004/0149211 A1
(43) Pub. Date: Aug. 5, 2004

(54) Systems including heated shower heads for thin film deposition and related methods

(76) Inventors: Jae-Young Ahn, Seongnam-si (KR); Myoung-Bum Lee, Seoul (KR); Jin-Gyun Kim, Suwon-si (KR)

Correspondence Address: MYERS BIGEL SIBLEY & SAJOVEC, PO BOX 37428, RALEIGH, NC, 27627, US

(21) Appl. No.: 10/621,585

(22) Filed: Jul. 17, 2003

(30) Foreign Application Priority Data
Jul. 18, 2002 (KR) 2002-41952

(51) Int. Cl. C23C 16/00

(52) U.S. Cl. 118/715; 427/248.1; 118/724

(57) ABSTRACT

A deposition apparatus is disclosed for depositing a layer on a substrate such as a semiconductor wafer. The deposition apparatus may include a process chamber, and a susceptor in the process chamber with the susceptor being configured to receive a substrate for depositing a thin layer thereon. The deposition apparatus may also include a showerhead on a side of the process chamber with the showerhead being configured to receive reaction gases and to introduce the reaction gases into the process chamber. The showerhead may include a heating element therein for heating reaction gases prior to introducing the reaction gases into the reaction chamber. Related methods are also discussed.

### RELATED APPLICATIONS

This application claims the benefit of priority from Korean Patent Application No. 2002-41952 field Jul. 18, 2002, the disclosure of which is hereby incorporated herein in its entirety by reference.

### FIELD OF THE INVENTION

The present invention relates to the manufacture of semiconductor devices and more particularly to depositing layers on substrates.

### BACKGROUND OF THE INVENTION

In general, when manufacturing semiconductor devices, a layer to be used as a dielectric or conductive material of the device can be formed on the surface of a substrate, such as a semiconductor wafer, by diffusing a gaseous chemical (vapor) onto the wafer, thereby facilitating a chemical reaction in which the layer is formed. Chemical vapor deposition processes available for forming such a dielectric or conductive layer can be classified as chemical vapor deposition (CVD) or atomic layer deposition (ALD). Chemical vapor deposition processes can be further classified as atmosphere pressure chemical vapor deposition (APCVD), low pressure chemical vapor deposition (LPCVD) or plasma enhanced chemical vapor deposition (PECVD).

Because low pressure chemical vapor deposition generally proceeds in a process chamber at relatively high temperatures, a layer formed on the wafer may have high thermal stress and cracks thereon may easily occur.

Though plasma enhanced chemical vapor deposition may proceed in a process chamber at relatively low temperatures, a plasma generator may be provided relatively distant from the process chamber, so that a layout of the apparatus may be complicated. In addition, because radicals generated in a plasma generator may be carried through a long pipe and supplied to the process chamber, radicals may recombine during transfer. Similar problems may also occur in atomic layer deposition.

### SUMMARY OF THE INVENTION

According to embodiments of the present invention, a deposition system may be provided for depositing a thin layer on a substrate such as a semiconductor wafer. This deposition system may include a process chamber, and a susceptor in the process chamber with the susceptor being configured to receive a substrate for depositing a thin layer thereon. The deposition system may also include a showerhead on a side of the process chamber with the showerhead being configured to receive reaction gases and to introduce the reaction gases into the process chamber. The showerhead may also include a heating element therein for heating reaction gases prior to introducing the reaction gases into the reaction chamber. The showerhead can also be configured to spray the reaction gases into the process chamber in parallel with a substrate received on the susceptor.

In addition, the showerhead may include a housing, at least one inlet port through which the reaction gases are received into the showerhead, and a spray plate adjacent the process chamber through which reaction gases are introduced into the process chamber. Moreover, the heating element may include a heating wire in the housing between the inlet port and the spray plate. More particularly, the heating wire comprises a catalytic material such as tungsten, and the heating wire may be a coiled wire. The housing can also include first and second terminals therein with the first and second ends of the heating wire being respectively connected to the first and second terminals, and each of the first and second terminals may include an elastic connecting portion to which the heating wire is connected. The housing can also include insulators that electrically insulate the terminals from conductive portions of the housing.

In addition, the showerhead can include a cooling portion configured to cool an outer portion of the housing, and the cooling portion may include a duct on an outer portion of the housing with the duct being configured to provide circulation of a cooling fluid therethrough. The showerhead can include a plurality of plenums therein such that each plenum receives at least one respective reaction gas and such that reaction gases from the plenums are introduced into the process chamber without prior mixing of the reaction gases between plenums within the showerhead. A first of the plenums may include a heating element therein configured to heat gases passing through the first plenum, and a second of the plenums can be free of a heating element. The first plenum with the heating element may also include an extended portion such that the first plenum extends further from the process chamber than the second plenum with the heating element being located in the extended portion of the first plenum. A duct may also be included on the extended portion of the first plenum wherein the duct is configured to provide circulation of a cooling fluid therethrough.

The susceptor can be configured to receive a substrate for depositing a thin layer thereon through atomic layer deposition and/or chemical vapor deposition. A boat can also be included in the process chamber with the boat supporting the first susceptor and at least a second susceptor with each susceptor being configured to receive at least one substrate for deposition of a thin layer thereon.

According to additional embodiments of the present invention, a method of depositing a thin layer on a substrate may include receiving a reaction gas in a showerhead adjacent a process chamber, and heating the reaction gas in the showerhead. After heating the reaction gas in the showerhead, the heated reaction gas may be introduced into the process chamber for deposition of the thin layer on the substrate in the process chamber. Moreover, the heated reaction gas can be introduced into the process chamber parallel to the substrate. Heating the reaction gas may include heating the reaction gas with a heating wire, and the heating wire may comprise a catalytic material such as tungsten.

More particularly, receiving a reaction gas in a showerhead may include receiving a first reaction gas in a first plenum of the showerhead, heating the reaction gas may include heating the first reaction gas in the first plenum, and introducing the heated reaction gas may include introducing the first heated reaction gas into the process chamber. In addition, a second reaction gas may be received in a second plenum of the showerhead, and the second reaction gas may be introduced into the process chamber for deposition of the thin layer on the substrate without heating the second reaction gas prior to introduction into the process chamber.

### BRIEF DESCRIPTION OF THE DRAWINGS

FIG. 1 is a side view illustrating a deposition system according to embodiments of the present invention.

FIG. 2 is a top view of the deposition system of FIG. 1.

FIG. 3 is a sectional view of the deposition system of FIG. 1.

FIG. 4 is a perspective view illustrating a showerhead according to embodiments of the present invention.

FIG. 5 is a sectional view taken along line I-I of FIG. 4.

FIG. 6 is a perspective view illustrating a shower head according to additional embodiments of the present invention.

FIG. 7 is a sectional view taken along line II-II of FIG. 6.

FIG. 8 is a perspective view illustrating a showerhead according to yet additional embodiments of the present invention.

FIG. 9 and FIG. 10 are sectional views taken along line III-III and line IV-IV of FIG. 8.

FIG. 11 is a perspective view illustrating a showerhead according to still additional embodiments of the present invention.

FIG. 12 is a sectional view taken along line V-V of FIG. 11.

### DESCRIPTION OF THE PREFERRED EMBODIMENT

The present invention now will be described more fully with reference to the accompanying drawings, in which preferred embodiments of the invention are shown. This invention may, however, be embodied in many different forms and should not be construed as being limited to the embodiments set forth herein; rather, these embodiments are provided so that this disclosure will be thorough and complete and will fully convey the concept of the invention to those skilled in the art. In the drawings, the sizes of elements are exaggerated for clarity. It will also be understood that when an element is referred to as being “coupled” or “connected” to another element, it can be directly coupled or connected to the other element, or intervening elements may also be present. When an element is referred to as being “directly coupled” or “directly connected” to another element, no intervening elements are present. It is also noted that like reference numerals may be used to designate identical or corresponding parts throughout the several views.

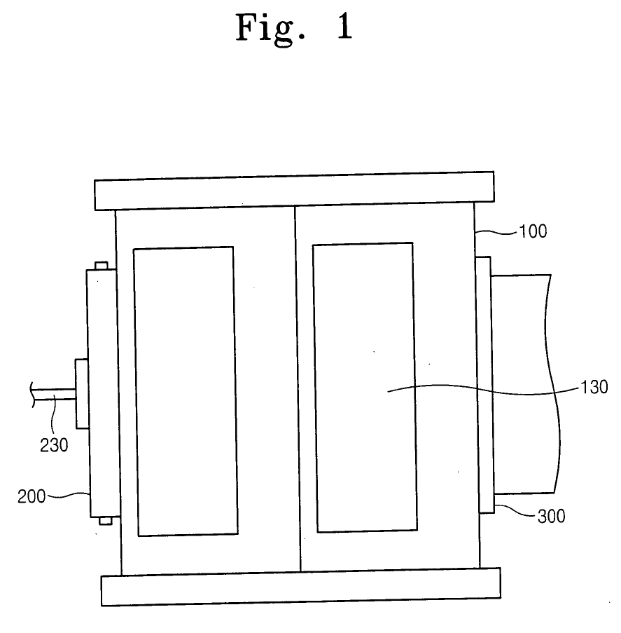

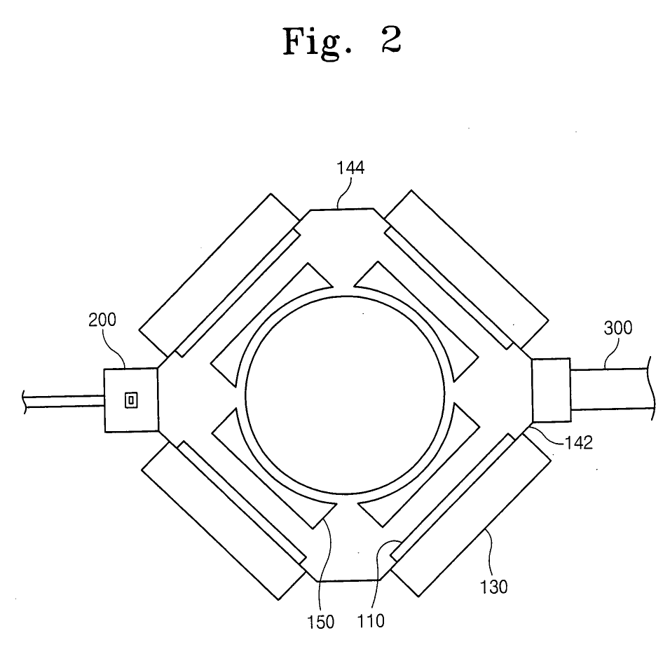

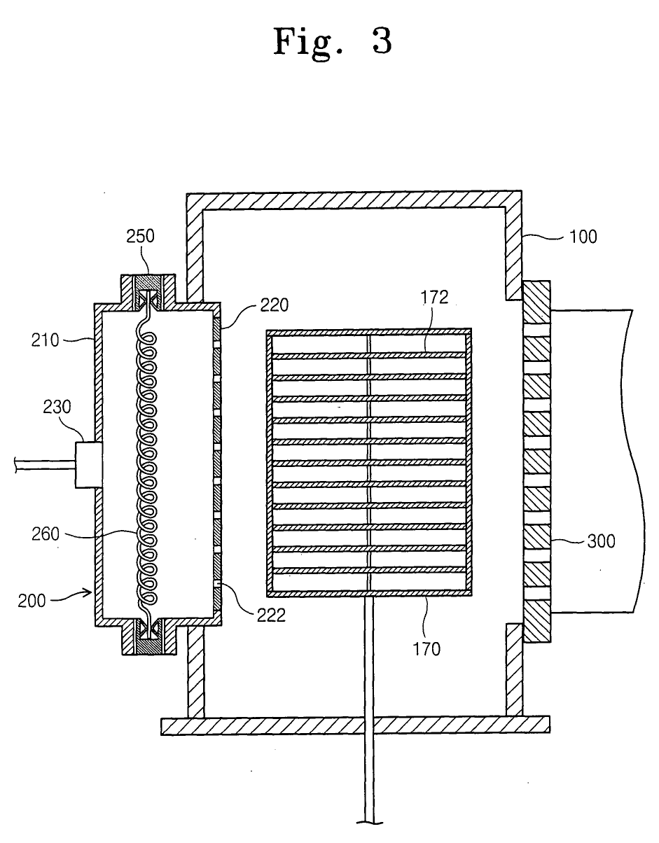

FIGS. 1, 2, and 3 are respectively side, top, and sectional views illustrating a deposition system according to embodiments of the present invention. The system includes a process chamber 100, a boat 170, a showerhead 200, and an exhaust 300.

The process chamber 100 has four wide main-sidewalls 142 and four narrow sub-sidewalls 144. Radiant heat sources 130 are located on the exterior of the process chamber 100. The process chamber 100 is kept at a moderate temperature by heat transferred from the radiant heat sources 130, so that gases that are supplied to the process chamber 100 can be adsorbed on substrates (such as semiconductor wafers) therein. The quartz windows 110 can be installed on the inside of the main-sidewalls 142 and radiant heat energy can be transmitted from the exterior of the process chamber 100 to the interior of the process chamber 100 through the quartz windows 110. Diffuser shield plates 150 can be located between the quartz windows 110 and the interior of the process chamber 100. The diffuser shield plates 150 may diffuse heat energy emitted from the radiant heat sources 130.

The boat 170 is located at the interior of the process chamber 100. The boat 170 may include a plurality of susceptors 172, and substrates are placed on the susceptors 172. The boat 170 may rotate during a process, so that layers may be more uniformly deposited on the substrates. The substrates can be placed on the boat 170 in a loader (not shown) located below the process chamber 100.

The showerhead 200 can be installed on one sub-sidewall 144 and can have sufficient length to uniformly spray gases to all substrates which are placed on the boat 170. The exhaust 300 can be installed on a sub-sidewall 144 opposite of the showerhead 200, and may be formed having a length the same as that of the showerhead 200. The gases can be sprayed in the process chamber 100 in parallel with surfaces of the substrates through the showerhead 100 so that deposition layers can be formed uniformly on all substrates.

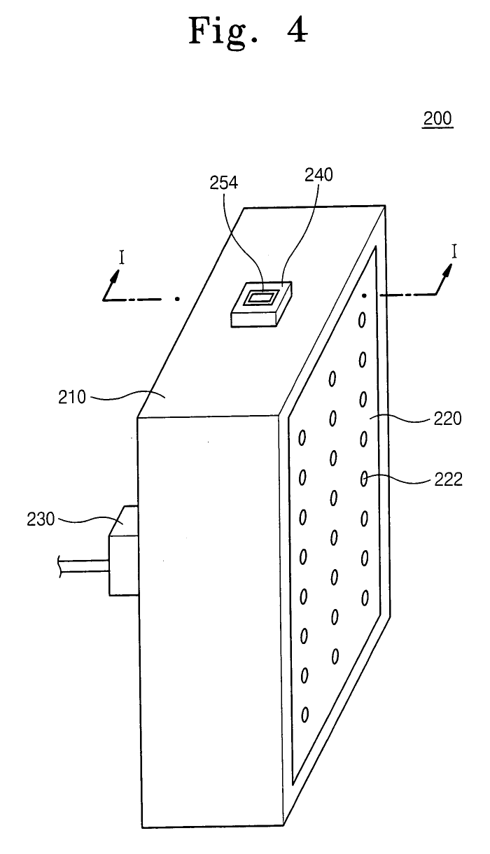

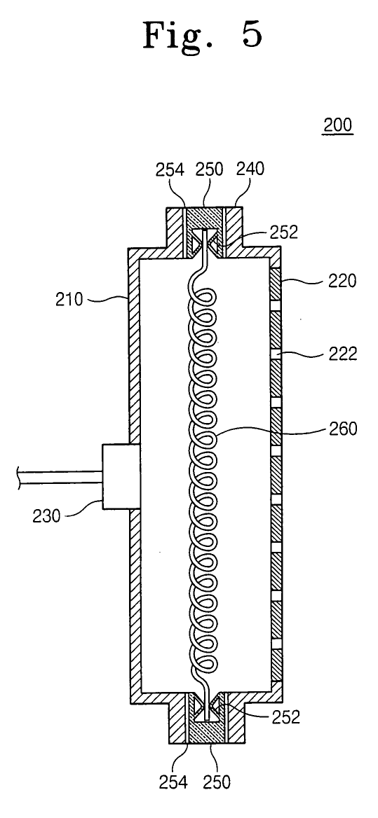

FIG. 4 is a perspective view illustrating the showerhead 200 according to embodiments of the present invention, and FIG. 5 is a sectional view taken along line I-I of FIG. 4. Referring to FIGS. 4 and 5, the showerhead 200 may include a housing 210, a heating element, and a cooling element (not shown). The housing 210 may include four side walls, the spray plate 220 and an inlet plate. The spray plate 220 can be installed on a rear side of the housing 210 adjacent to the process chamber 100, and the inlet plate having an inlet port 230 can be installed on a front side of the housing 210, that is, on a side opposite of the spray plate 220. The inlet plate may be joined to the housing 210, for example, by screws or welding. Optionally, the inlet plate and the housing 210 may be integrally formed.

The spray plate 220 may be joined/separated to/from the housing 210 and an o-ring may be inserted between the spray plate 220 and the housing 210 for sealing. A plurality of spray holes 222 can be formed on the spray plate 220 and gases or radicals in the showerhead 200 can be supplied to the process chamber 100 through the spray holes 222. Optionally slits may be formed on the spray plate 220 instead of or in addition to the spray holes 222.

The showerhead 200 may include the heating element to decompose the reactant gases that come in the housing 100 through the inlet port 230. The term decompose means separation of a chemical combination into constituents. The heating element may include a heating wire 260 (or filament) and terminals 250. The projections 240 may be formed on two opposing side walls that face each other and the terminals 250 may be inserted in the projection 240. The heating wire 260 is located in the housing 100 and both ends of the heating wire 260 are connected with respective terminals 250. Also, a plurality of heating wires 260 may be installed on the housing 100.

Referring to FIG. 5, the terminals 250 each have a connecting portion 252 at one end thereof, and ends of the wire 260 are connected with respective terminals 250. The connecting portions 252 may have two elastic members with triangular shape. A space with a width smaller than the diameter of the wire 260 is formed between the two elastic members. The heating wire 260 is pushed toward the space between two elastic members to connect the heating wire 260 with terminals 250. Insulator members 254 may be inserted between each of the terminals 250 and the housing 210.

The heating wire 260 can be formed as a coil to supply a relatively wide heat transfer area, thereby increasing an amount of heat that can be transferred to reactant gases. The heating wire 260 can be made of tungsten to catalyze the decomposition of the reactant gases. The showerhead 200 can include a cooling element such as a duct (not shown) surrounding the housing 210 through which cooling water can flow. The cooling may reduce heating of the housing 210 of the showerhead 200 due to heat emitted from the heating wire 260.

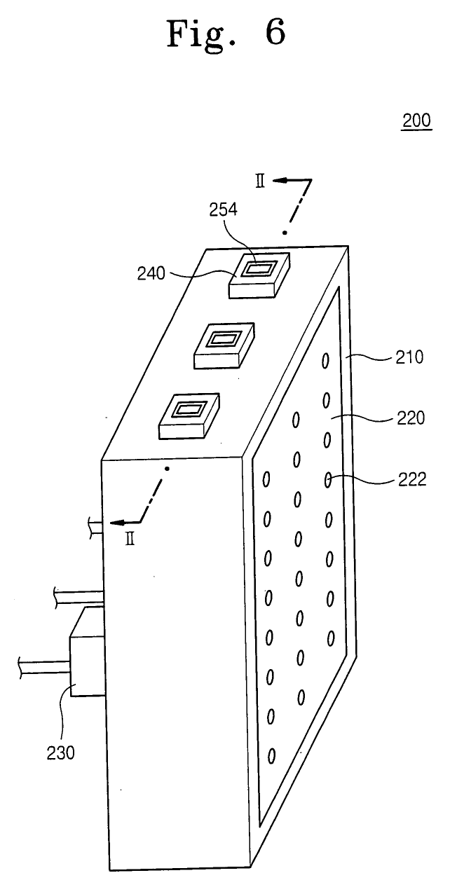

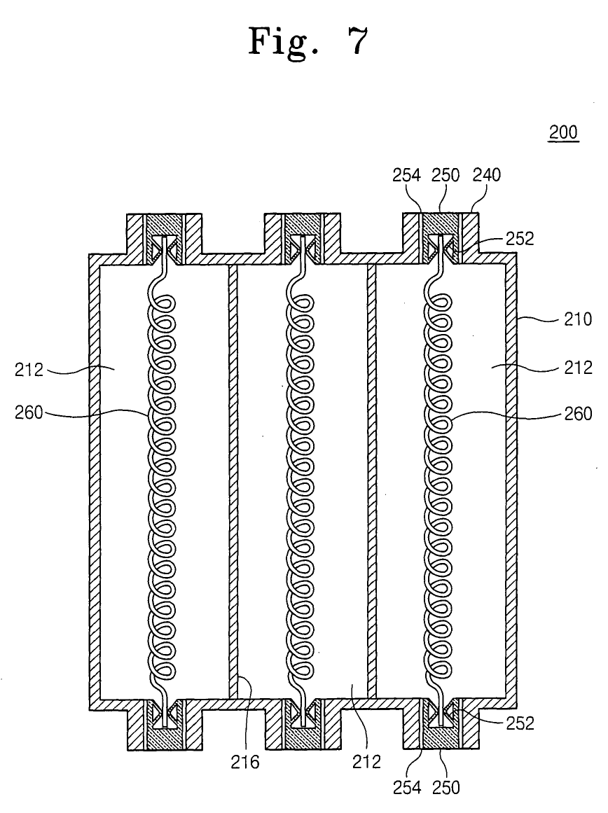

FIG. 6 is a perspective view illustrating another example of a showerhead 200 and FIG. 7 is a sectional view taken along line II-II of FIG. 6. Referring to FIGS. 6 and 7, the housing 210 may include three plenums 212 separated by partitions 216. Each of the plenums 212 may have a respective inlet port 230 where the reactant gases are introduced, and the spray plate 220 may include a respective column of holes 222 for each plenum. The terminals 250 are inserted at the both ends of each plenum 212, and a heating element 260 such as a tungsten wire can be connected with the terminals 250 in each plenum. A different kind of gas may flow in a each plenum 212 without mixture. The gases can be supplied to the process chamber 100 through the spray plate 220 after being decomposed in respective plenums 212.

According to embodiments of the present invention, because the reactant gases are decomposed in the showerhead 200, the process can proceed in the chamber 100 at a lower temperature than may otherwise be used in a conventional vertical furnace. Thermal stress induced in the substrate may thus be reduced during deposition of the layer, and cracking of the deposited layer may be reduced.

Because the reactant gases can be decomposed in the showerhead 200 and supplied to the process chamber 100 without delay, a recombination of radicals can be reduced.

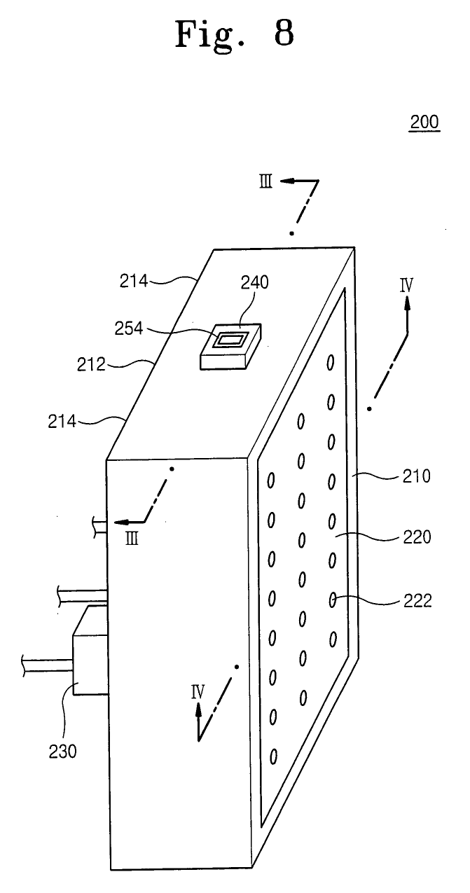

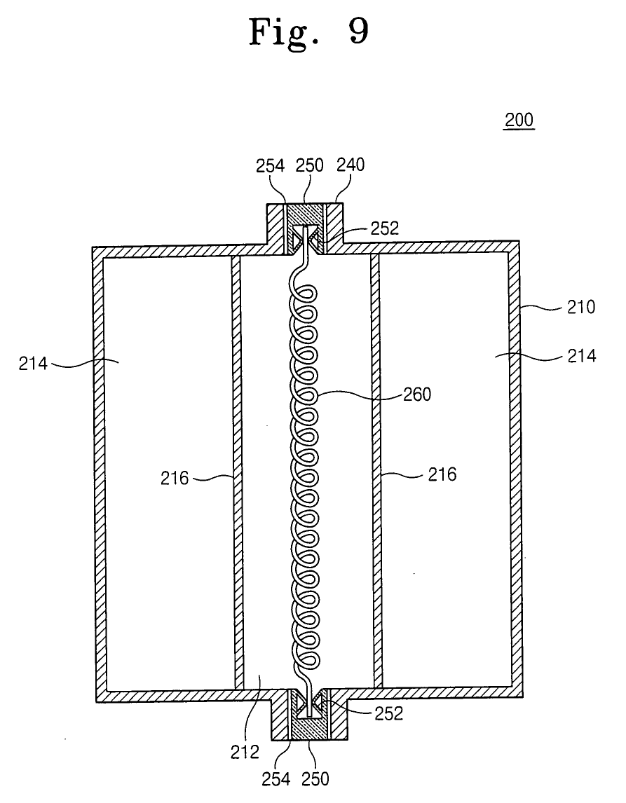

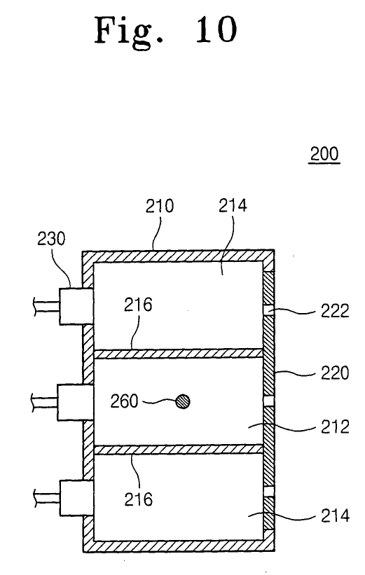

FIG. 8 is a perspective view illustrating the showerhead 200 according to additional embodiments of the present invention. FIGS. 9 and 10 are sectional views taken along line III-III and line IV-IV of FIG. 8. Referring to FIG. 8, the showerhead 200 can include a housing 210, a heating element and a cooling element as discussed with respect to FIGS. 4 and 5. The housing 210 of FIGS. 8-10 includes a plurality of plenums 212 and 214 separated by partitions 216, so that the reactant gases are supplied to the process chamber 100 without mixture.

Referring to FIGS. 9 and 10, the length of the center plenum 212 may be the same as that of the side plenums 214. An inlet plate having an inlet port 230 can be installed on each of the plenums 212 and 214. The spraying plate 220 is located on a side of the plenums opposite the inlet plates. First reactant gases can be supplied to center plenum 212 and second reactant gases can be supplied to the side plenums 214. The first gases can be gases that are supplied to the process chamber 100 after decomposition, and the second gases can be gases that are supplied to the process chamber 100 without decomposition.

The terminals 250 are provided at opposite sides of the center plenum 212 and the heating wire 260 can be connected with the terminals 212. For example, when forming an aluminum oxidation layer on a substrate using an atomic layer deposition system according to embodiments of the present invention, tri-metal aluminum (Al(CH₃)₃, TMA) composed of aluminum and a metal ligand can be supplied to the process chamber 100 through one or both of the side plenums 214. Then water vapor can be supplied to the process chamber 100 through the center plenum 212. The water vapor can be decomposed in oxygen ligand and hydrogen ligand in the center plenum 212. Before the water vapors are supplied to the chamber 100, an inert gas (such as nitrogen gas) may be provided to the process chamber 100 through one or both of the side plenums 214 or a different spray pipe. A number of heated plenums 212 and unheated plenums 214 may be changed according to a number of the reactant gases to be used.

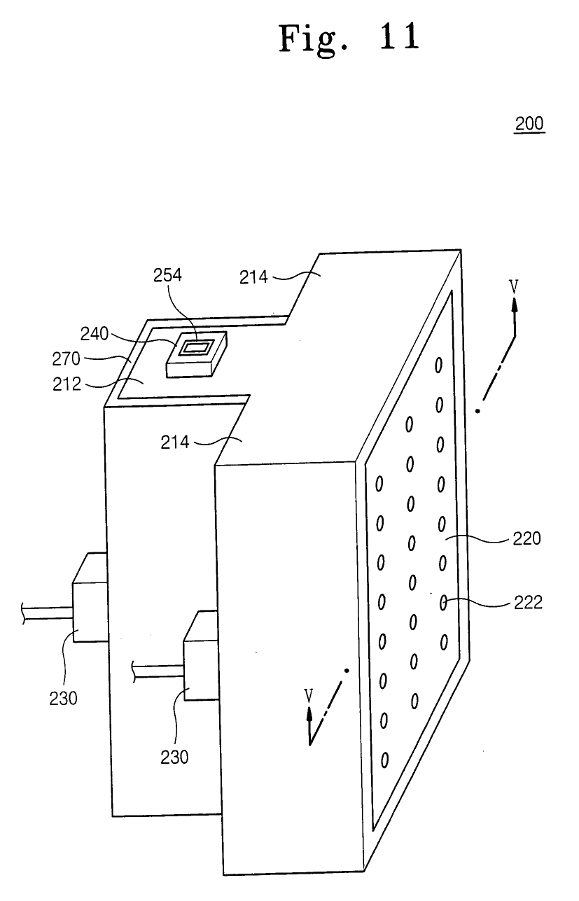

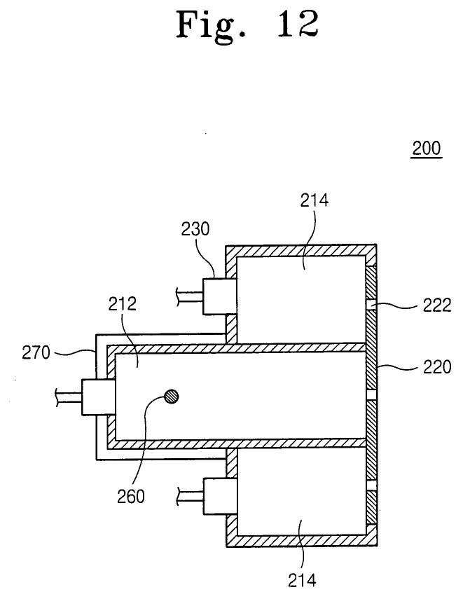

FIG. 11 is a perspective view showing a showerhead 200 according to yet additional embodiments of the present invention, and FIG. 12 is a sectional view taken along line V-V of FIG. 11. In embodiments illustrated in FIGS. 11 and 12, the heat emitted by the heating wire 260 (such as a tungsten wire) located in the central plenum 212 is transferred to side walls of the second plenums 214. Accordingly, reactant gases in the side plenums 214 may be decomposed by the heat. According to embodiments illustrated in FIGS. 11 and 12, the housing 210 has the central plenum 212 supplying first reactant gases to the process chamber 100 after decomposing them and the side plenums 214 may supply additional reactant gases to the process chamber 100 without decomposing them. The central plenum 212 with the heating wire 260 can be longer than the side plenums 214. In other words, the central plenum 212 can have an extended portion projecting from the central plenum 214. The heating wire 260 (such as a tungsten wire) can be installed on the extended portion in the central plenum 212 to reduce heating of the side plenums 214 due to heat that is generated from the heating wire 260.

A duct 270 may be installed surrounding the extended portion of the central plenum 212, and cooling water may flow through the duct 270. The duct 270 may optionally be installed on entire outer wall of the central plenum 212 or the housing 210.

If it is necessary to decompose two or more different reactant gases, the reactant gases can be supplied to the process chamber 100 through the same central plenum 212. Optionally the housing 210 may comprise a plurality of the central plenums 212 and the reactant gases may be supplied to the process chamber 100 through respective central plenums 212.

A deposition system according to embodiments of the present invention may be used to process a single substrate or to simultaneously process a plurality of substrates. In addition, atomic layer deposition and/or chemical vapor deposition may be performed in a deposition system according to embodiments of the present invention

According to embodiments of the present invention, a deposition system may provide improved deposition characteristics and structures. According to embodiments of the present invention, a deposition system may include a process chamber, a boat on which substrates are placed, and a showerhead that sprays gases in parallel with surfaces of substrates placed on the boat.

The showerhead may include a housing and a heating element for decomposing the gases. An inlet port connected with a pipe can be installed on a side of the housing and a spray plate spraying the decomposed gases into the process chamber can be installed on the opposite side of the housing. The heating element may include a heating wire and terminals. The terminals can be provided at opposite sides of the housing and the heating wire can be connected with the terminals. The heating wire can be made of a catalytic material (such as tungsten) to accelerate decomposition of the gases, and the heating wire can be formed in a coil. Insulators may be inserted between the housing and the terminals, and a cooling element can be provided in the outer wall of the housing.

According to additional embodiments of the present invention, the showerhead may include a plurality of plenums and a heating element may be installed in at least one but not all of the plenums.

According to yet additional embodiments of the present invention, the showerhead may have at least a first plenum where first gases flow and at least a second plenum where second gases flow. A heating element such as a hot wire can be installed in the first plenum, and the first plenum can have an extended portion projecting from the second plenum. In addition, a heating element such as a heating wire can be located in the extended portion to reduce heating of the second plenum due to heat that is generated from the heating element.

While this invention has been particularly shown and described with reference to preferred embodiments thereof, it will be understood by those skilled in the art that various changes in form and details may be made therein without departing from the spirit and scope of the invention as defined by the appended claims and equivalents.

What is claimed is:

1. A deposition system for depositing a layer on a substrate, the deposition system comprising:
a process chamber;
a susceptor in the process chamber, the susceptor being configured to receive a substrate for depositing a layer thereon;
a showerhead on a side of the process chamber, the showerhead being configured to receive reaction gases and to introduce the reaction gases into the process chamber, the showerhead including a heating element therein for heating reaction gases prior to introducing the reaction gases into the reaction chamber.

2. A deposition system according to claim 1 wherein the showerhead is further configured to spray the reaction gases into the process chamber in parallel with a substrate received on the susceptor.

3. A deposition system according to claim 2 wherein the showerhead comprises:
a housing,
at least one inlet port through which the reaction gases are received into the showerhead; and
a spray plate adjacent the process chamber through which reaction gases are introduced into the process chamber;
wherein the heating element comprises a heating wire in the housing between the inlet port and the spray plate.

4. A deposition system according to claim 3 wherein the heating wire comprises a catalytic material.

5. A deposition system according to claim 4 wherein the heating wire comprises tungsten.

6. A deposition system according to claim 3 wherein the heating wire comprises a coiled wire.

7. A deposition system according to claim 3 wherein the housing includes first and second terminals therein and wherein first and second ends of the heating wire are respectively connected to the first and second terminals.

8. A deposition system according to claim 7 wherein each of the first and second terminals comprises an elastic connecting portion to which the heating wire is connected.

9. A deposition system according to claim 8 wherein the housing further includes insulators that electrically insulate the terminals from conductive portions of the housing.

10. A deposition system according to claim 3 wherein the showerhead further comprises a cooling portion configured to cool an outer portion of the housing.

11. A deposition system according to claim 10 wherein the cooling portion comprises a duct on an outer portion of the housing, wherein the duct is configured to provide circulation of a cooling fluid therethrough.

12. A deposition system according to claim 1 wherein the showerhead comprises a plurality of plenums therein such that each plenum receives at least one respective reaction gas such that reaction gases from the plenums are introduced into the process chamber without prior mixing of the reaction gases between plenums within the showerhead.

13. A deposition system according to claim 12 wherein a first of the plenums includes a heating element therein configured to heat gases passing through the first plenum and wherein a second of the plenums is free of a heating element.

14. A deposition system according to claim 13 wherein the first plenum includes an extended portion such that the first plenum extends further from the process chamber than the second plenum and wherein the heating element is located in the extended portion of the first plenum.

15. A deposition system according to claim 14 further comprising a duct on the extended portion of the first plenum wherein the duct is configured to provide circulation of a cooling fluid therethrough.

16. A deposition system according to claim 1 wherein the susceptor is configured to receive a substrate for depositing a layer thereon through atomic layer deposition.

17. A deposition system according to claim 1 wherein the susceptor is configured to receive a substrate for depositing a layer thereon through chemical vapor deposition.

18. A deposition system according to claim 1 further comprising a boat in the process chamber wherein the boat supports the first susceptor and at least a second susceptor with each susceptor being configured to receive at least one substrate for deposition of a layer thereon.

19. A method of depositing a layer on a substrate in a process chamber, the method comprising:
receiving a reaction gas in a showerhead adjacent the process chamber;
heating the reaction gas in the showerhead; and
after heating the reaction gas in the showerhead, introducing the heated reaction gas into the process chamber for deposition of the layer on the substrate in the process chamber.

20. A method according to claim 19 wherein receiving a reaction gas in a showerhead comprises receiving a first reaction gas in a first plenum of the showerhead, wherein heating the reaction gas comprises heating the first reaction gas in the first plenum, and introducing the heated reaction gas comprises introducing the first heated reaction gas into the process chamber, the method further comprising:
receiving a second reaction gas in a second plenum of the showerhead; and
introducing the second reaction gas into the process chamber for deposition of the layer on the substrate without heating the second reaction gas prior to introduction into the process chamber.
